(19) United States
(12) Patent Application Publication
(10) Pub. No.: US 2003/0159274 A1
(43) Pub. Date: Aug. 28, 2003

(54) Bump forming system employing attracting and compressing device

(75) Inventor: Shinobu Isobe, Tateyama-shi (JP)

Correspondence Address: COHEN, PONTANI, LIEBERMAN & PAVANE, 551 FIFTH AVENUE, SUITE 1210, NEW YORK, NY, 10176, US

(73) Assignee: UMC Japan, Tateyama-shi (JP)

(21) Appl. No.: 10/366,455

(22) Filed: Feb. 13, 2003

(30) Foreign Application Priority Data
Feb. 28, 2002 (JP) 2002-054458

(51) Int. Cl. H01L 23/02; B23P 19/00

(52) U.S. Cl. 29/740; 257/678; 29/832; 29/834

(57) ABSTRACT

A system for forming bumps on pads which are provided on a target at low cost and with high productivity. The target is a semiconductor wafer or a semiconductor chip. The system has an attracting and compressing device for attracting bump materials for bumps, and compressing and bonding the bump materials onto the pads. The attracting and compressing device may have an attracting and compressing plate in which hollow portions for attracting and holding the bump materials are formed, the hollow portions being one of holes, concave portions, and grooves. The attracting and compressing plate can collectively attract the bump materials to be compressed onto a predetermined area which corresponds to one of a wafer, a chip, and a block. The attracting and compressing device may have a finishing plate which has a flat surface for pressing and bonding the bump materials, and an ultrasonic wave generating device.

### BACKGROUND OF THE INVENTION

1. Field of the Invention

The present invention relates to a bump forming system, and in particular, relates to a system for forming bumps on a semiconductor wafer such as a silicon wafer or a semiconductor chip such as a silicon chip, at low cost and with high productivity.

2. Description of the Related Art

In conventional semiconductor devices such as ICs, LSIs, and VLSIs, bumps are formed at specific positions (typically, on pads) on a silicon wafer by printing, ball-bump forming, plating, wire-bonding, or the like.

For example, in printing, a metal mask is used for printing solder paste on pads which are formed on a silicon wafer, and in the next step, the wafer is subjected to thermal processing at a specific temperature, thereby forming bumps on the pads.

In ball-bump forming, each pad formed on a silicon wafer is coated in advance with a paste such as flux, and a ball made of solder or gold is placed on the paste. In the next step, the wafer is subjected to thermal processing at a high temperature (i.e., reflow), thereby forming bumps on the pads.

When employing plating, pads formed on a silicon wafer are subjected to gold plating (which may be electrolytic plating) by using a mask, thereby forming bumps on the pad.

In wire-bonding, an end of a gold wire is thermally or electrically processed to have a circular shape, and this circular portion is compressed and bonded onto a pad on a silicon wafer. In the next step, the gold wire other than the circular portion is cut and removed, thereby forming a bump on the pad.

In the above-explained conventional bump forming methods, solder may be used as a bump material. In this case, in order to improve solder wetting, a pad, on which a metal thin film has been vapor-deposited, should be further coated with flux; thus, the number of production processes is increased and productivity is degraded, thereby causing problems such as increase in the production cost.

Additionally, in plating or wire-bonding, the bump material is gold, and yield and productivity is low, so that the production cost is high.

### SUMMARY OF THE INVENTION

In consideration of the above circumstances, an object of the present invention is to provide a system for forming bumps at low cost and with high productivity.

The present invention provides a bump forming system for forming bumps on pads which are provided on a target, the target being one of a semiconductor wafer and a semiconductor chip, the system comprising:

an attracting and compressing device for attracting bump materials for bumps to be formed, and compressing and bonding the bump materials onto the pads.

According to this structure, bumps having desired shapes and bonding strength can be efficiently formed on the pads. Therefore, high-quality bumps can be formed at low cost.

The attracting and compressing device may have an attracting and compressing plate in which hollow portions for attracting and holding the bump materials are formed, the hollow portions being one of holes, concave portions, and grooves.

Typically, the attracting and compressing plate collectively attracts the bump materials to be compressed onto a predetermined area which corresponds to one of a wafer, a chip, and a block.

Preferably, the attracting and compressing device has a finishing plate which has a flat surface for pressing and bonding the bump materials. Accordingly, the height of the bumps can be equalized. Therefore, even when the bumps are used in a liquid crystal display plate or the like, in which electric connection is established by contacting bumps to specific portions, desired characteristics and performance can be obtained.

As a typical example, the attracting and compressing device has an ultrasonic wave generating device for generating ultrasonic waves by which the bump materials are compressed and bonded. Accordingly, sufficient bonding strength can be obtained even when the bump materials are pressed with weak force. Therefore, desired shapes of the bumps can be obtained and maintained, and in comparison with the conventional method of simply pressing bumps from the upper side, deformation of the bumps can be prevented. Additionally, in comparison with the conventional plating, it is possible to improve bump-forming accuracy.

As another typical example, the attracting and compressing device has a heat generating device for generating heat by which the bump materials are thermally compressed and bonded.

### BRIEF DESCRIPTION OF THE DRAWINGS

FIG. 1 is a sectional view showing the general structure of the bump forming system as an embodiment of the present invention.

FIG. 2 is a sectional view showing the structure of the attracting and compressing plate in the bump forming system of the embodiment.

FIGS. 3A to 3D are diagrams showing the steps in the method of forming bumps by using the bump forming system of the embodiment.

### DESCRIPTION OF THE PREFERRED EMBODIMENTS

Hereinafter, an embodiment of the bump forming system according to the present invention will be explained with reference to the drawings.

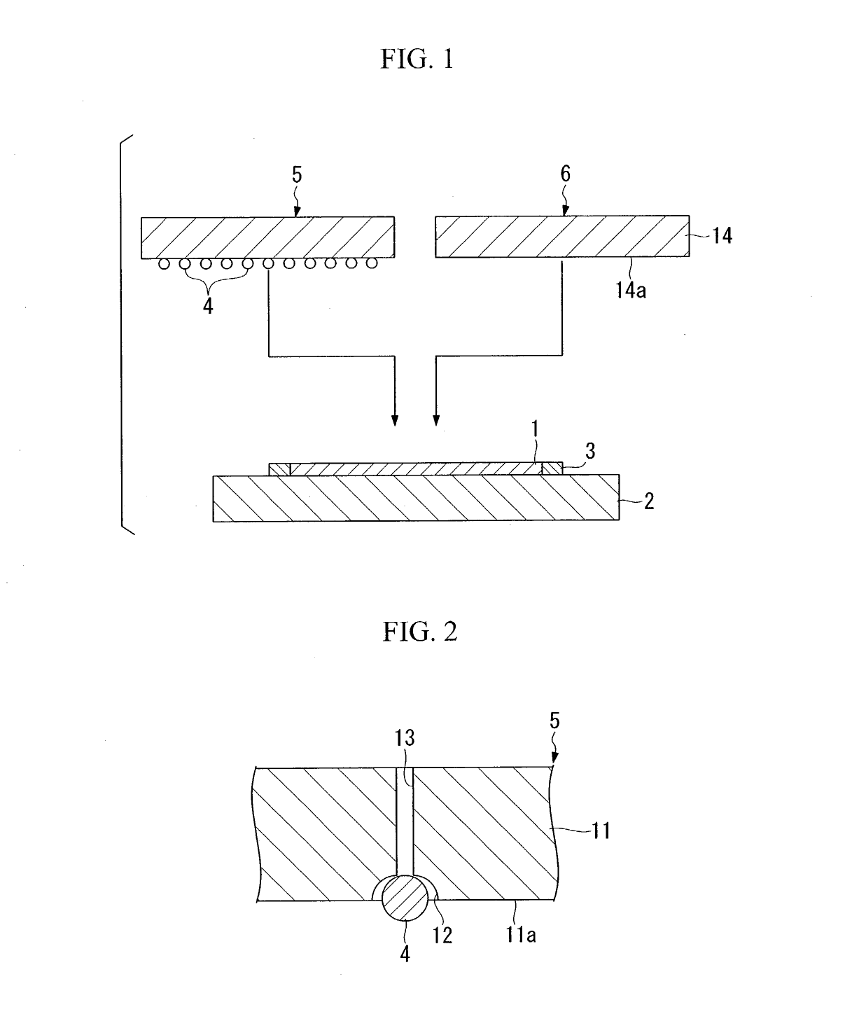

FIG. 1 is a diagram showing the general structure of the bump forming system as an embodiment of the present invention.

In FIG. 1, reference numeral 1 indicates a silicon wafer (corresponding to the target in the present invention), reference numeral 2 indicates a stage on which the silicon wafer I is placed; reference numeral 3 indicates a chuck (i.e., fastening device) for fastening the silicon wafer 1 onto the stage 2, reference numeral 4 indicates gold balls (corresponds to the bump materials of the present invention), reference numeral 5 indicates an attracting and compressing plate (corresponds to the attracting and compressing device of the present invention) for performing vacuum attraction and ultrasonic compression of the gold balls 4, and reference numeral 6 indicates a finishing plate for pressing the gold balls 4 so as to provide a specific shape to each ball.

As a typical example, the silicon wafer 1 has a diameter of 8 inches (approximately, 203 mm), and the wafer is fastened to the stage 2 via the chuck 3, where three portions along the peripheral side of the wafer are actually fastened.

The gold balls 4 are bump material whose major component is gold. The diameter of the ball is determined according to the shape of the pad on the silicon wafer I or the shape of a bump to be formed; however, generally, the diameter is approximately 30 to 50 μm. Additionally, according to required characteristics, solder balls made of Pb—Sn solder, Pb—Sn—Ag solder or the like may be used instead of using gold balls 4.

The structure of the attracting and compressing plate 5 will be explained with reference to FIG. 2. As shown in the figure, the panel plate 11 has a flat plane 11a (which is a major plane) on which concave portions 12, each having an approximately hemispherical shape, for attracting and holding the gold balls 4 are formed, where the positions of the concave portions 12 respectively correspond to the positions of the pads formed on the silicon wafer 1. A passage 13, an end of which is connected to each concave portion 12, is formed through the plate 11, where the other end of passage is connected to a vacuum pump or the like, which is used in vacuum attraction of the gold balls 4.

The peripheral edge of each concave portion 12, that is, the boundary between the concave portion 12 and the flat plane 11a is made round (i.e., chamfered), and the radius of the concave portion 12 is larger than the radius of the gold ball 4 to be attracted, so that the concave portion 12 and the flat plane 11a are smoothly connected and the gold balls 4 can be reliably attracted and removed. Here, the concave portion 12 should have a shape necessary for vacuum-attracting the gold ball 4; thus, another shape like a cone may be employed, or the section of the concave portion may have an elliptical shape.

The entire surface of the plate 11 is made of metal such as stainless steel or titanium, which has a superior environmental resistance. In order to prevent the gold balls 4 from welding, the entire surface of the plate 11 may be coated with fluororesin or ceramics (such as oxide ceramics). To this plate 11, ultrasonic waves having a specific frequency are applied by a known ultrasonic wave generating device. The ultrasonic waves should have a strength necessary for vibrating the gold balls 4 and directly binding the balls into the pads.

The thickness of the above coating using ceramics or the like is not specifically limited, but must secure a minimum thickness for protecting the plate.

On the other hand, the entire plate 11 may be made of a material for preventing the gold balls from welding onto the plate, such as fluororesin or ceramics (such as oxide ceramics).

As shown in FIG. 1, the finishing plate 6 is made of a panel plate 14 which has a flat plane 14a (a major plane of the panel plane) for pressing the gold balls 4.

The attracting and compressing plate 5 and the finishing plate 6 can approach or leave the stage 2 by a known positioning (or moving) mechanism (not shown).

Below, the method of forming bumps on aluminum pads on the silicon wafer 1, by using the bump forming system of the present embodiment, will be explained.

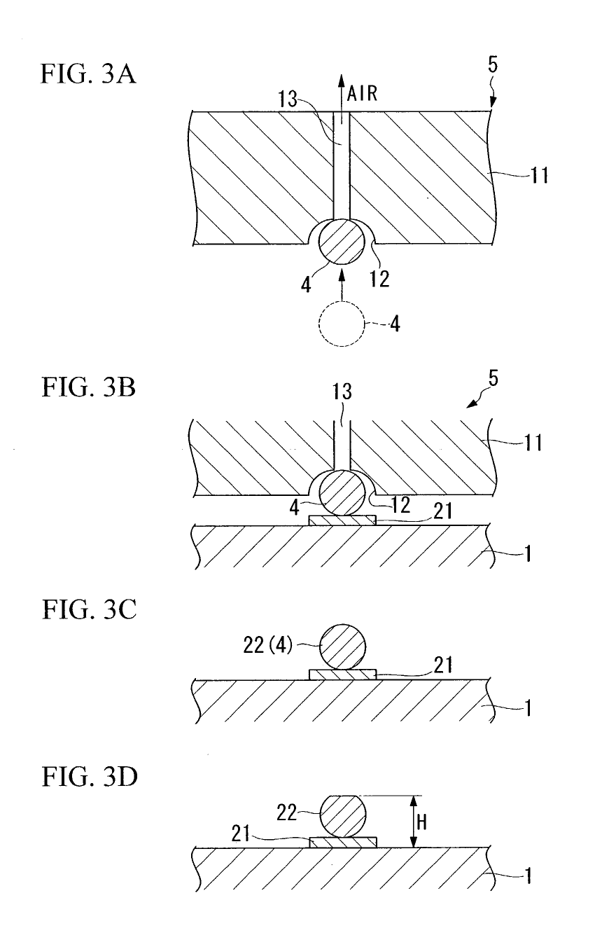

First, as shown in FIG. 3A, the attracting and compressing plate 5 is made close to the gold balls 4, which are contained in a container and have the same shape, and the inside of each concave portion 12 is decompressed via the passage 13 by using a vacuum pump or the like, so that each gold ball 4 is attracted into the concave portion 12.

When each gold ball 4 is contained in the concave portion 12, the inside of the concave portion 12 is in a sealed state, so that no more air is drawn from the concave portion. Therefore, the state that the gold balls 4 have been contained in all concave portions 12 can be detected by monitoring the air-drawing state from the concave portions 12. Here, according to necessity, a monitoring system using a camera or the like may be employed, so as to visually or automatically monitor the state of containment of the gold balls 4 by using the camera or the like.

In the next step, as shown in FIG. 3B, the attracting and compressing plate 5 is moved above the silicon wafer 1 using a positioning (or moving) mechanism (not shown), so as to performing suitable positioning between the attracting and compressing plate 5 and the silicon wafer 1. Accordingly, the plate 11 (of the attracting and compressing plate 5) is made close to the silicon wafer 1, so that each gold ball 4, which has been attracted to the concave portion of the attracting and compressing plate 5, is placed onto the aluminum pad 21. In this process, a known positioning apparatus may be used for adjusting the relative position between the gold ball 4 and the aluminum pad 21, or the positioning may be automatically performed using a camera or the like.

In the following step, ultrasonic waves having a specific frequency are applied to the plate 11 so as to vibrate each gold ball 4 and directly compress and bond the gold ball onto the aluminum pad 21, thereby producing a bump 22.

In the compressing and bonding process, the shape of the concave portion 12 is transferred to the gold ball 4; thus, the height of each gold ball 4 is not constant.

Such unevenness in height causes no problem when, for example, the silicon wafer 1 is divided into chips (by dicing) and each chip is mounted onto a printed wiring board by electrically connecting the chip using melted solder or the like. However, when electrical connection is established by contact (e.g., in a liquid crystal display plate), the above unevenness in height affects the performance and thus produces a problem which is not insignificant.

Therefore, the bumps 22 are pressed by the finishing plate 6 from the upper side, so as to equalize the height H of each bump 22 at a specific height (refer to FIG. 3D).

Here, the gold balls 4 are collectively transferred onto a wafer; however, the gold balls 4 may be collectively transferred onto a chip or a block (i.e., a divided portion), or may be transferred one by one. In accordance with each case, the shape and arrangement of the concave portions 12 in the attracting and compressing plate 5, and tools to be used, such as a transfer mechanism for transferring a target object (e.g., a chip), may be suitably determined.

As explained in detail above, the bump forming system of the present embodiment has the attracting and compressing plate 5 for (i) vacuum-attracting the gold balls 4 and (ii) compressing and bonding the attracted gold balls by using ultrasonic waves; thus, bumps having desired shapes and bonding strength can be efficiently formed on the pads. Therefore, high-quality bumps can be formed at low cost.

In addition, the gold balls 4 are bonded using ultrasonic waves; thus, sufficient bonding strength can be obtained even when the gold balls 4 are pressed with weak force. Therefore, desired shapes of the bumps can be obtained and maintained, and in comparison with the conventional method of simply pressing bumps from the upper side, deformation of the bumps can be prevented. Additionally, in comparison with the conventional plating, it is possible to improve bump-forming accuracy.

In addition, the finishing plate 6 is provided; thus, the height of the bumps can be equalized. Therefore, even when the bumps are used in a liquid crystal display plate or the like, in which electric connection is established by contacting bumps to specific portions, desired characteristics and performance can be obtained.

Furthermore, the bump forming system can be flexibly realized as a manually-operated system, an automatic system having a wafer loader, or the like. Therefore, various kinds of systems having different specifications can be realized by suitably setting and changing the number and shape of each of the attracting and compressing plate 5 and the finishing plate 6.

In addition, instead of the ultrasonic wave generating device, a heat generating device may be provided to the attracting and compressing plate 5, so as to thermally compress and bond the gold balls 4.

What is claimed is:

1. A bump forming system for forming bumps on pads which are provided on a target, the target being one of a semiconductor wafer and a semiconductor chip, the system comprising:
an attracting and compressing device for attracting bump materials for bumps to be formed, and compressing and bonding the bump materials onto the pads.

2. A bump forming system as claimed in claim 1, wherein the attracting and compressing device has an attracting and compressing plate in which hollow portions for attracting and holding the bump materials are formed, the hollow portions being one of holes, concave portions, and grooves.

3. A bump forming system as claimed in claim 2, wherein the attracting and compressing plate collectively attracts the bump materials to be compressed onto a predetermined area which corresponds to one of a wafer, a chip, and a block.

4. A bump forming system as claimed in claim 1, wherein the attracting and compressing device has a finishing plate which has a flat surface for pressing and bonding the bump materials.

5. A bump forming system as claimed in claim 2, wherein the attracting and compressing device has a finishing plate which has a flat surface for pressing and bonding the bump materials.

6. A bump forming system as claimed in claim 1, wherein the attracting and compressing device has an ultrasonic wave generating device for generating ultrasonic waves by which the bump materials are compressed and bonded.

7. A bump forming system as claimed in claim 1, wherein the attracting and compressing device has a heat generating device for generating heat by which the bump materials are thermally compressed and bonded.
